(19) United States
(12) Patent Application Publication
(10) Pub. No.: US 2010/0127237 A1
(43) Pub. Date: May 27, 2010

(54) HIGH BRIGHTNESS LIGHT EMITTING DIODE STRUCTURE AND A METHOD FOR FABRICATING THE SAME

(76) Inventors: Chih-Sung Chang, Hsinchu City (TW); Liang-Jyi Yan, Taipei County (TW)

Correspondence Address: Muncy, Geissler, Olds & Lowe, PLLC, 4000 Legato Road, Suite 310, FAIRFAX, VA, 22033, US

(21) Appl. No.: 12/324,635

(22) Filed: Nov. 26, 2008

(51) Int. Cl. H01L 33/00

(52) U.S. Cl. 257/13; 438/29; 257/E33.005

(57) ABSTRACT

The preset invention discloses a high-brightness LED structure and a method for fabricating the same. The LED structure of the present invention comprises a silicon substrate, a metal adhesion layer, a metal reflection layer, an N-type semiconductor layer, an active layer, and a P-type semiconductor layer, which are sequentially stacked. In the method of the present invention, the P-type semiconductor layer, active layer, N-type semiconductor layer and metal reflection layer are sequentially deposited on an N-type substrate; next, the metal reflection layer is bonded to the metal adhesion layer having been formed on the silicon substrate; then, the N-type substrate is removed. The present invention uses the silicon substrate to replace the light-absorptive GaAs substrate. Therefore, the present invention can promote light efficiency and enhance brightness.

### FIELD OF THE INVENTION

The present invention relates to an LED structure, particularly to a high-brightness LED structure and a method for fabricating the same.

### BACKGROUND OF THE INVENTION

LED (Light Emitting Diode) is a luminescent element, wherein current is applied to a III-V group compound semiconductor, and energy is released in form of light in the recombination of electrons and holes. LED does not burn as an incandescent lamp. Further, LED has a small volume, long service life, low driving voltage, high response speed and superior vibration resistance. Thus, LED can satisfy the demand for lightweight and compactness and has become a very popular product in daily living.

LED has greatly advanced in the performance and efficiency thereof and has been extensively used in daily living. Via different compound semiconductors and structures, LED may emit red, orange, yellow, green blue, violet, infrared, or ultraviolet light. Now, LED has been widely used in outdoor signboards, brake lights, traffic signs and display devices.

In principle, an LED is a sandwich structure having an N-type semiconductor layer, an active layer and a P-type semiconductor layer, which are formed via depositing four elements-aluminum, gallium, indium and phosphor, or alternatively formed of another semiconductor material, such as GaP (gallium phosphide), GaAlAs (gallium aluminum arsenide), GaAs (gallium arsenide). LED has a PN structure and a unidirectional conductivity. LED is generally deposited on a GaAs substrate. However, GaAs is a light-absorptive material and absorbs a portion of light emitted by the LED epitaxial layer. Thus, the light generated by LED is not fully utilized, and the brightness thereof is decreased.

### SUMMARY OF THE INVENTION

The primary objective of the present invention is to provide a high-brightness LED structure and a method for fabricating the same.

The present invention proposes a high-brightness LED structure, which comprises a silicon substrate, a metal adhesion layer, a metal reflection layer, an N-type semiconductor layer, an active layer, and a P-type semiconductor layer, wherein the metal adhesion layer is stacked on the silicon substrate; the metal reflection layer is stacked on the metal adhesion layer; the N-type semiconductor layer is stacked on the metal reflection layer; the active layer is stacked on the N-type semiconductor layer; and the P-type semiconductor layer is stacked on the active layer.

The present invention also proposes a method for fabricating a high-brightness LED structure, which comprises steps: providing an N-type substrate; sequentially stacking on the N-type substrate a P-type semiconductor layer, an active layer, an N-type semiconductor layer and a metal reflection layer to form a first semi-product; preparing a silicon substrate; stacking a metal adhesion layer on the silicon substrate to form a second semi-product; bonding the metal reflection layer of the first semi-product to the metal adhesion layer of the second semi-product; and etching away the N-type substrate of the first semi-product to form the high-brightness LED structure of the present invention.

The present invention exempts the LED structure from using a light-absorptive GaAs substrate and uses the metal reflection layer to enhance light efficiency, whereby the generated light is fully utilized and the brightness is greatly increased.

### BRIEF DESCRIPTION OF THE DRAWINGS

FIG. 1 is a sectional view of an LED structure according to the present invention;

FIG. 2A is a sectional view of a first semi-product of the LED structure according to the present invention;

FIG. 2B is a sectional view of a second semi-product of the LED structure according to the present invention;

FIG. 3 is a sectional view of the structure of the bonded first and second semi-products of the LED structure according to the present invention;

FIG. 4 is a sectional view of the structure of the bonded first and second semi-products shown in FIG. 3 with the N-type substrate and the buffer layer removed according to the present invention.

### DETAILED DESCRIPTION OF THE PREFERRED EMBODIMENTS

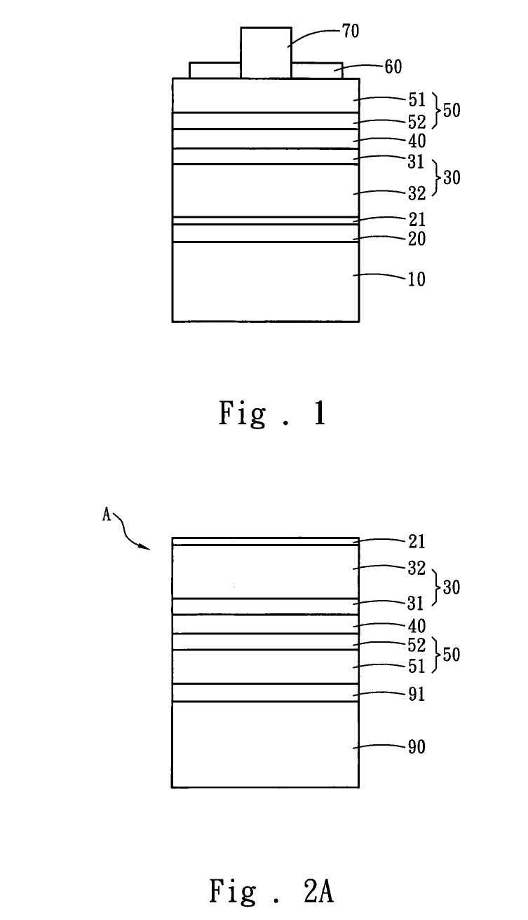

Below, the technical contents of the present invention are described in detail with the embodiments. However, it should be understood that the embodiments are only to exemplify the present invention but not to limit the scope of the present invention. Refer to FIG. 1. The LED structure of the present invention comprises a silicon substrate 10, a metal adhesion layer 20, a metal reflection layer 21, an N-type semiconductor layer 30, an active layer 40, and a P-type semiconductor layer 50, wherein the metal adhesion layer 20 is stacked on the silicon substrate 10; the metal reflection layer 21 is stacked on the metal adhesion layer 20; and the N-type semiconductor layer 30 is stacked on the metal reflection layer 21. The N-type semiconductor layer 30 is made of a material selected from the group consisting of GaAs (gallium arsenide), GaP (gallium phosphide), GaInAlP (gallium indium aluminum phosphide), InAlP (indium aluminum phosphide), or GaAlAs (gallium aluminum arsenide).

The active layer 40 is stacked on the N-type semiconductor layer 30. The active layer 40 is a quantum well containing a period structure of GaInAlN (gallium indium aluminum nitride). The N-type semiconductor layer 30 includes an N-type cladding layer 31 and an N-type window layer 32. The N-type window layer 32 contacts the metal reflection layer 21, and the N-type cladding layer 31 contacts the active layer 40.

The P-type semiconductor layer 50 is stacked on the active layer 40. The P-type semiconductor layer 50 is made of a material selected from the group consisting of GaAs (gallium arsenide), GaP (gallium phosphide), GaInAlP (gallium indium aluminum phosphide), InAlP (indium aluminum phosphide), or GaAlAs (gallium aluminum arsenide). The P-type semiconductor layer 50 includes a P-type ohmic contact layer 51 and a P-type cladding layer 52, and the P-type cladding layer 52 contacts the active layer 40. A protection layer 60 is stacked on the P-type semiconductor layer 50. The protection layer 60 is made of silicon dioxide or silicon nitride. A contact pad 70 penetrates the protection layer 60 to contact the P-type semiconductor layer 50.

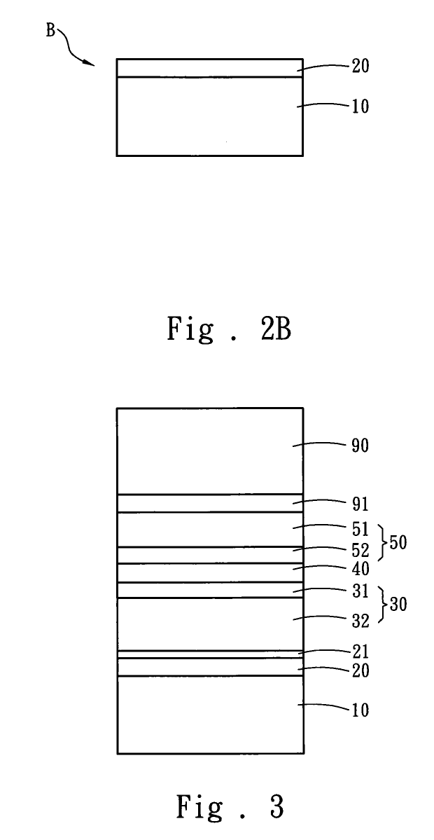

Refer to FIG. 2A and FIG. 2B. The method for fabricating a high-brightness LED structure of the present invention comprises steps: providing an N-type substrate 90 with a buffer layer 91 stacked on the N-type substrate 90, wherein the buffer layer 91 is of the P-type or N-type conductivity; and sequentially stacking on the buffer layer 91 of the N-type substrate 90 a P-type semiconductor layer 50, an active layer 40, an N-type semiconductor layer 30 and a metal reflection layer 21 to form a first semi-product A (shown in FIG. 2A), wherein the active layer 40 may be a quantum well containing a period structure of GaInAlN (gallium indium aluminum nitride), and wherein the P-type semiconductor layer 50 and N-type semiconductor layer 30 are made of a material selected from the group consisting of GaAs (gallium arsenide), GaP (gallium phosphide), GaInAlP (gallium indium aluminum phosphide), InAlP (indium aluminum phosphide), or GaAlAs (gallium aluminum arsenide).

In stacking the P-type semiconductor layer 50, a P-type ohmic contact layer 51 is stacked firstly, and then a P-type cladding layer 52 is stacked. In stacking the N-type semiconductor layer 30, an N-type cladding layer 31 is stacked firstly, and then an N-type window layer 32 is stacked. The method of the present invention also comprises steps: preparing a silicon substrate 10; and stacking a metal adhesion layer 20 on the silicon substrate 10 to form a second semi-product B (shown in FIG. 2B).

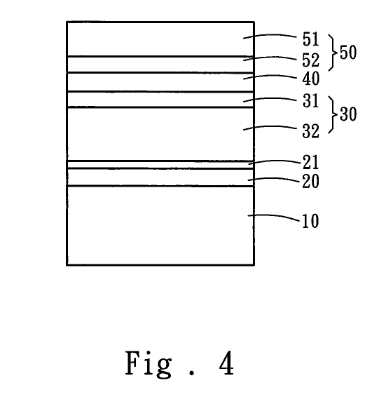

Refer to FIG. 3 and FIG. 4. The method of the present invention also comprises steps: bonding the metal reflection layer 21 of the first semi-product A to the metal adhesion layer 20 of the second semi-product B; and etching away the N-type substrate 90 and the buffer layer 91 of the first semi-product A.

Refer to FIG. 1 again. The method of the present invention may further comprise steps: stacking a protection layer 60 on the P-type semiconductor layer 50 of the first semi-product A, wherein the protection layer 60 is made of silicon dioxide or silicon nitride; and forming a contact pad 70 penetrating the protection layer 60 and contacting the P-type semiconductor layer 50.

In conclusion, the present invention proposes a high-brightness LED structure and a method for fabricating the same, which needn't use a GaAs substrate, and which uses a metal reflection layer to reflect light. Therefore, the present invention can increase light efficiency and provide a high-brightness LED for users.

What is claimed is:

1. A high brightness light emitting diode structure comprising
a silicon substrate;
a metal adhesion layer stacked on said silicon substrate;
a metal reflection layer stacked on said metal adhesion layer;
an N-type semiconductor layer stacked on said metal reflection layer;
an active layer stacked on said N-type semiconductor layer; and
a P-type semiconductor layer stacked on said an active layer.

2. The high brightness light emitting diode structure according to claim 1, wherein a protection layer is stacked on said P-type semiconductor layer.

3. The high brightness light emitting diode structure according to claim 2, wherein said protection layer is made of silicon dioxide or silicon nitride.

4. The high brightness light emitting diode structure according to claim 2, wherein a contact pad penetrates said protection layer to contact said P-type semiconductor layer.

5. The high brightness light emitting diode structure according to claim 1, wherein said P-type semiconductor layer includes a P-type ohmic contact layer and a P-type cladding layer, and said P-type cladding layer contacts said active layer.

6. The high brightness light emitting diode structure according to claim 1, wherein said active layer is a quantum well containing a period structure of GaInAlN (gallium indium aluminum nitride).

7. The high brightness light emitting diode structure according to claim 1, wherein said N-type semiconductor layer includes an N-type cladding layer and an N-type window layer; said N-type window layer contacts said metal reflection layer, and said N-type cladding layer contacts said active layer.

8. The high brightness light emitting diode structure according to claim 1, wherein said N-type semiconductor layer is made of a material selected from a group consisting of GaAs (gallium arsenide), GaP (gallium phosphide), GaInAlP (gallium indium aluminum phosphide), InAlP (indium aluminum phosphide), or GaAlAs (gallium aluminum arsenide).

9. The high brightness light emitting diode structure according to claim 1, wherein said P-type semiconductor layer is made of a material selected from a group consisting of GaAs (gallium arsenide), GaP (gallium phosphide), GaInAlP (gallium indium aluminum phosphide), InAlP (indium aluminum phosphide), or GaAlAs (gallium aluminum arsenide).

10. A method for fabricating a high brightness light emitting diode structure, comprising steps:
providing an N-type substrate and sequentially stacking on said N-type substrate a P-type semiconductor layer, an active layer, an N-type semiconductor layer and a metal reflection layer to form a first semi-product;
preparing a silicon substrate and stacking a metal adhesion layer on said silicon substrate to form a second semi-product; and
bonding said metal reflection layer of said first semi-product to said metal adhesion layer of said second semi-product and etching away said N-type substrate of the first semi-product.

11. The method for fabricating a high brightness light emitting diode structure according to claim 10, wherein a buffer layer is stacked on said N-type substrate firstly, and said buffer layer is of a P-type conductivity or an N-type conductivity; then, said P-type semiconductor layer is stacked on said buffer layer; after said first semi-product is bonded to said second semi-product, said N-type substrate and said buffer layer are removed with an etching method.

12. The method for fabricating a high brightness light emitting diode structure according to claim 10, wherein a protection layer is stacked on said P-type semiconductor layer of said first semi-product.

13. The method for fabricating a high brightness light emitting diode structure according to claim 12, wherein said protection layer is made of silicon dioxide or silicon nitride.

14. The method for fabricating a high brightness light emitting diode structure according to claim 12, wherein after said protection layer has been stacked, a contact pad is formed to penetrate said protection layer and contact said P-type semiconductor layer.

15. The method for fabricating a high brightness light emitting diode structure according to claim 10, wherein in stacking said P-type semiconductor layer, a P-type ohmic contact layer is stacked firstly, and then a P-type cladding layer is stacked.

16. The method for fabricating a high brightness light emitting diode structure according to claim 10, wherein said active layer is a quantum well containing a period structure of GaInAlN (gallium indium aluminum nitride).

17. The method for fabricating a high brightness light emitting diode structure according to claim 10, wherein in stacking said N-type semiconductor layer, an N-type cladding layer is stacked firstly, and then an N-type window layer is stacked.

18. The method for fabricating a high brightness light emitting diode structure according to claim 10, wherein said N-type semiconductor layer is made of a material selected from a group consisting of GaAs (gallium arsenide), GaP (gallium phosphide), GaInAlP (gallium indium aluminum phosphide), InAlP (indium aluminum phosphide), or GaAlAs (gallium aluminum arsenide).

19. The method for fabricating a high brightness light emitting diode structure according to claim 10, wherein said P-type semiconductor layer is made of a material selected from a group consisting of GaAs (gallium arsenide), GaP (gallium phosphide), GaInAlP (gallium indium aluminum phosphide), InAlP (indium aluminum phosphide), or GaAlAs (gallium aluminum arsenide).
